(19) United States
(12) Patent Application Publication
(10) Pub. No.: US 2005/0157823 A1
(43) Pub. Date: Jul. 21, 2005

(54) Technique for improving viterbi decoder performance

(76) Inventor: Raghavan Sudhakar, Austin, TX (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/761,637

(22) Filed: Jan. 20, 2004

(51) Int. Cl. H03D 1/00

(52) U.S. Cl. 375/341; 375/340

(57) ABSTRACT

Optimizing a decoding algorithm used in various telecommunications protocols. Embodiments of the invention relate to a technique for decoding encoded data by reducing redundant calculations and memory accesses and better matching add-compare-select (ACS) operations with corresponding digital signal processing (DSP) instructions.

### FIELD

Embodiments of the invention relate to digital signal processing. More particularly, embodiments of the invention relate to a technique for improving the performance of a Viterbi decoder by reducing redundant branch metric calculations and memory accesses associated with add-compare-select (ACS) operations. Furthermore, embodiments of the invention relate to improving the match between_ACS operations and corresponding digital signal processing (DSP) instructions.

### BACKGROUND

Various algorithms may be used to decode data streams transmitted in a telecommunications system. For example, Viterbi decoding is a data decoding algorithm that is typically used in telecommunications systems in which various communication protocols, such as global system for mobile communications (GSM), general packet radio system (GPRS), wideband-code division multiple access (W-CDMA), and IEEE (institute of electrical and electronics engineers) 802.11a, are used. Decoding algorithms, such as Viterbi decoding, typically involve comparing the sequence of encoded symbols with various expected symbols by using metrics, such as Euclidean distance, and determining the most likely decoded state sequence corresponding to the received symbols.

The most likely decoded state is typically determined, at least in part, via traversing stages of a state sequence table known as a “trellis”, in which next input symbol states, or “stages”, are indicated as a function of current input symbol states sequences received from an encoder output. The sequence of stages that best match the input symbol sequences is typically referred to as a survivor path within the trellis.

FIG. 1 is a block diagram of a prior art Viterbi decoding scheme. In FIG. 1, an input symbol sequence is received by a branch metric unit (BMU), in which each symbol in the sequence is compared against a list of expected symbols. The relative distance between the expected symbols and the active symbols are calculated by the BMU in order to allow a path metric unit (PMU) to calculate a path through the trellis that corresponds to the most probable value of each of the received symbols in the sequence. Each most probable symbol value is then identified in a survivor memory updating unit (SMU), or “trace back” unit, to yield the properly decoded bit sequence representing the input symbol sequence.

The ACS butterfly diagram in FIG. 2a illustrates a manner in which the path metrics (PM_{2J}, PM_{2J+1}) corresponding to the next encoded bit sequence, represented by the 16 “next” stages indicated in the trellis diagram, is calculated from the current state path metrics (PM_{J}, PM_{J+N/2}) and the branch metric (BM_{J}), corresponding to the last-received encoded symbol represented by the bits, b₀ b₁ b₂, where “j” is the index of the state and “N” corresponds to the total possible states of the symbol. Branch metrics typically represent a deviation between a received symbol and an expected encoder output for each state transition on a bit-by-bit basis. The state transitions can be represented by the transition vectors of the trellis diagram.

The ACS diagram of FIG. 2b illustrates an implementation of the ACS butterfly diagram of FIG. 2a. In the “add” stage, the BM value of each received symbol corresponding to a j'th state (BM_{J}) is added or subtracted to or from the PM value of the j'th state (PM_{J}) and PM value of the state J+N/2 (PM_{J+N/2}). The two sums of the “add” stage are compared in the “compare” stage and the smaller of the two sums is selected of the ACS diagram in order to determine the path metric (PM_{2J}) of the next stage. The resulting PM values are then normalized to avoid numerical overflow. The decision bits (indicating which of the two sum is selected for each ACS operation) generated at each stage are saved for later-on use by SMU for trace back operation.

Signal decoders, such as Viterbi decoders, typically decode symbols of data according to a code rate, defined by k/n, in which n represents a number of bits in an encoded symbol to represent data consisting of k bits. Furthermore, a number of decoder state variables corresponding to the encoded symbols is typically referred to as a constraint length (K).

In prior art Viterbi decoding techniques, branch metric calculations are typically performed by using an n-bit correlator with a 2^{K} element look-up table of expected outputs. However, the above branch metric calculation technique can be inefficient in that it typically involves 2^{K-2}-2ⁿ⁻¹ redundant n-bit correlations. Furthermore, the above computations increase with the code rate (1/n), which is the ratio of the number of input bits and number of output bits of the encoder.

In other prior art Viterbi decoding techniques, branch metric calculation operations can be performed by computing the 2ⁿ⁻¹ unique branch metrics for each received symbol, and storing them as an ordered 2^{K} long branch metric vector for direct addressing by the ACS butterflies. This branch metric calculation technique, however, can require 2^{K-2} extra cycles for storing the branch metric vector.

FIGS. 3a and 3b illustrate the inputs, outputs and state transitions, respectively, for a 16-state, ⅓ rate encoder, the states of which are generated according to polynomials, 1+D+D³+D⁴, 1+D²+D⁴ and 1+D+D²+D³+D⁴, where “D” denotes a delay state of a unit of time. FIG. 3a, in particular, illustrates an encoder shift register having input signal, delay states S₄S₃S₂S₁, and output signal. The output signal, represented by the symbol, Y₁Y₂Y₃(n), may be transmitted to a decoder that uses at least one embodiment of the invention to decode the encoder output signal.

FIG. 3b illustrates one stage of a state table, or “trellis”, illustrating current and next data states that must be calculated in prior art Viterbi decoders for each decoded symbol value. Notice that for each bit that is encoded to a 3-bit encoder output symbol, 16 different possible states must be calculated by prior art Viterbi decoders.

Furthermore, FIG. 3b illustrates the state transitions corresponding to the input signal and the output signals of the encoder of FIG. 3a. FIG. 3b shows the decoder input states received from the encoder and the corresponding possible next states for each encoded data bit. In one embodiment of the invention, the number of calculations necessary to determine the next state corresponding to each current state is reduced, thereby improving decoder performance.

In calculating the path metrics of all N states for each symbol of encoded data, the prior art Viterbi decoding schemes can be computationally intensive. Furthermore, high encoded data transmission rates, such as those found in typical telecommunication protocols, can place further performance demands on a decoding algorithm. As data rates increase in transmission protocols due, for example, to increased transmission rates or to more elaborate encoding schemes involving larger or more complex data word transmissions, so does the complexity and performance demands on the decoder.

Decoding high-speed, highly encoded data streams may involve the increased use of digital signal processor (DSP) cycles and resources, because of the rate of mathematical computations that must be performed to decode each encoded data symbol. In typical telecommunications systems, this may necessitate either the use of high performance DSPs or a significant amount of processing resources in slower DSPs in order to decode a data stream while maintaining the rate of other operations within the telecommunications system. Either way, prior art Viterbi decoding techniques may cause increased system cost, power, and complexity in telecommunication systems in which they are implemented.

### BRIEF DESCRIPTION OF THE DRAWINGS

Embodiments of the invention are illustrated by way of example and not limitation in the figures of the accompanying drawings, in which like references indicate similar elements and in which:

FIG. 1 is a block diagram of a prior art decoding scheme.

FIG. 2a is an ACS butterfly diagram.

FIG. 2b is an implementation of the ACS butterfly diagram of FIG. 2a.

FIG. 3a illustrates a Viterbi encoding scheme used in conjunction with one embodiment of the invention.

FIG. 3b illustrates a stage of a state trellis indicating possible data state transitions of an encoded signal corresponding to one embodiment of the invention.

FIG. 4 is a flow chart illustrating operations involved in a decoding scheme according to one embodiment of the invention.

FIG. 5a is a table illustrating present and next state transitions for a 16-state ⅓ rate decoder according to one embodiment of the invention.

FIG. 5b is a set of equations used to model branch metrics calculations for 16-state, ⅓ rate Viterbi decoding according to one embodiment of the invention.

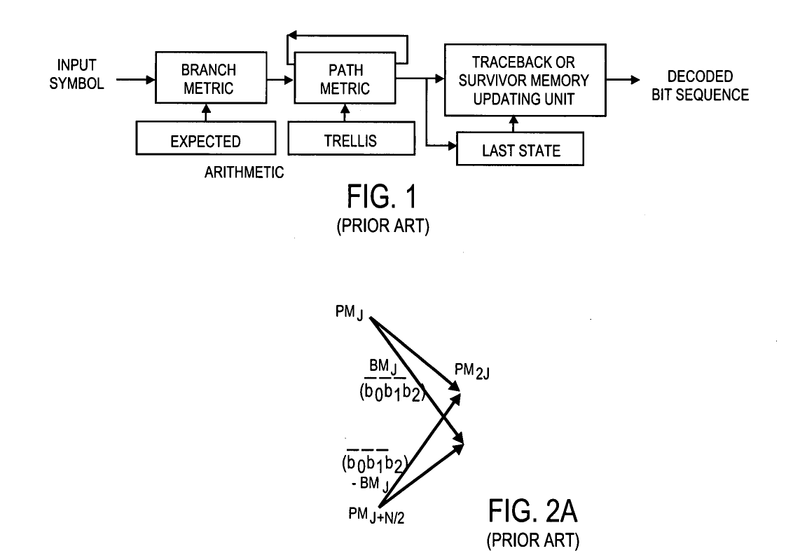

### DETAILED DESCRIPTION

Embodiments of the invention relate to digital signal processing. More particularly, embodiments of the invention relate to a technique for decoding encoded data by reducing redundant calculations and memory accesses and better matching add-compare-select (ACS) operations with corresponding digital signal processing (DSP) instructions.

Embodiments of the invention described herein may be applied to prior art DSP decoding schemes, such as the Viterbi decoding algorithm, or may be applied to other decoding schemes involving the detection and calculation of probable states of an encoded data stream. Although embodiments of the invention are frequently described herein with reference to the Viterbi decoding algorithm, one of ordinary skill in the art will appreciate that the applicability of principals taught with regard to embodiments of the invention may apply to other decoding schemes as well.

Embodiments of the invention involve decoding data symbols found in typical telecommunications protocols, such as GSM/GPRS, W-CDMA, and IEEE 802.11a, by finding the optimal path through a table, or “trellis”, of received and expected data in order to reduce the amount of calculations and memory access that must take place in order to decode a particular symbol or group of symbols. Symbols used in many telecommunications protocols typically represent delay states that indicate to a receiving device or computer program the location or length of various instructions or commands within a data stream. Decoding these delay states can involve multiple iterations of calculations and data accesses from memory that can limit the data throughput between telecommunications devices, such as cell phones, base stations, or computer equipment.

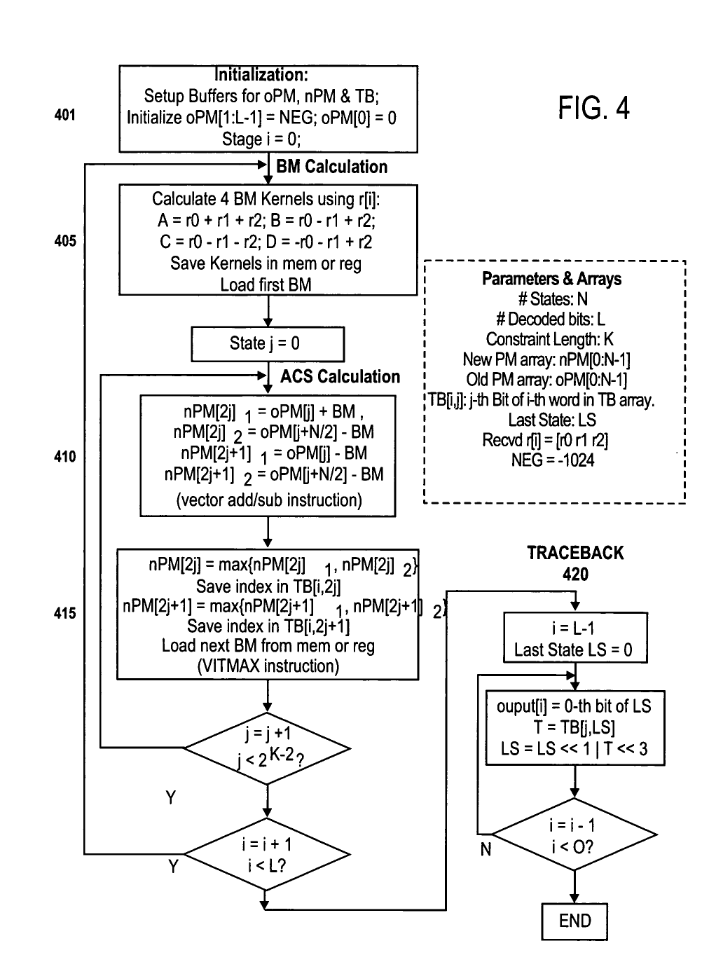

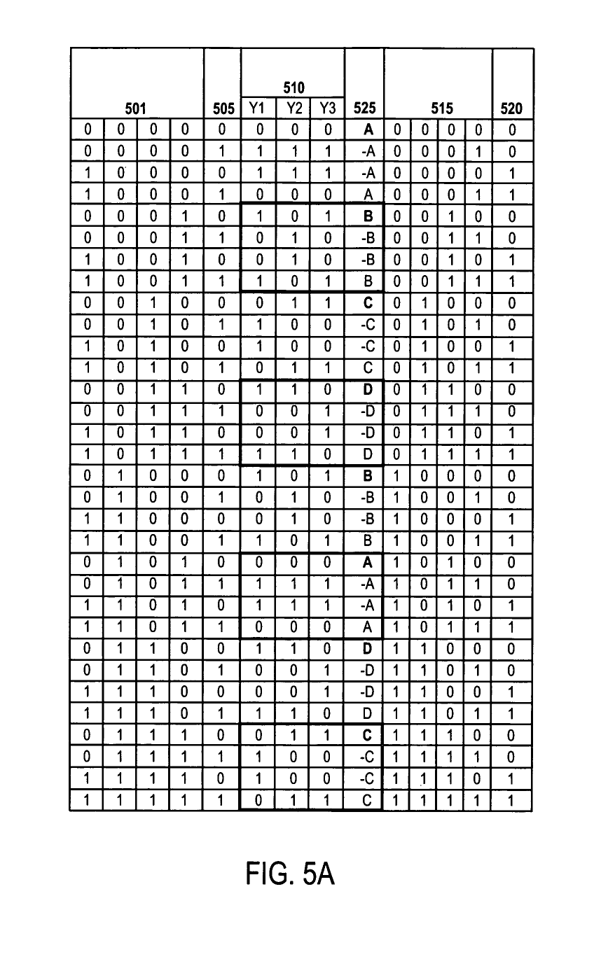

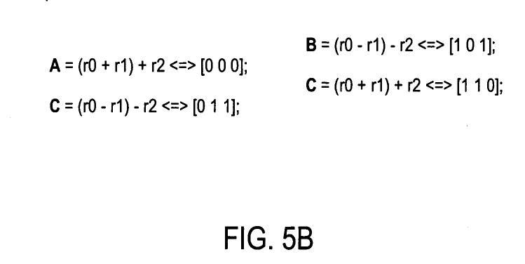

FIG. 4 is a flowchart illustrating a decoder scheme according to one embodiment of the invention involving a 16-state ⅓ rate Viterbi decoder. In the initialization operation 401, path metric buffers and trace back buffers are initialized. Four branch metric (BM) kernel equations are calculated at operation 405, which are saved in memory or a register. The BM kernel equations take advantage of the symmetric nature of the state transitions in the Viterbi decoder, explained below in reference to FIG. 5b. Branch metric calculations are made using each “j”'th bit of the “i”'th word. In one embodiment of the invention, “j” corresponds to first, second, and third bit of the encoded data that is to be decoded in a ⅓ rate decoder, and “i” corresponds to the first through the sixteenth possible encoded states received by a 16-state decoder.

The ACS calculations, in at least in one embodiment, include branch metric (BM) and path metric (PM) calculations to determine the most probable next state transitions for each current state. However, in other embodiments, the ACS calculations may not include the BM calculations. In FIG. 4, the ACS calculations include only PM calculations 410 and finding the maximum PM values 415, which correspond to the state transition having the highest correlation to the data received by the Viterbi decoder, and saving them.

After the ACS calculations are made, the minimum distance through the state trellis generated by making the ACS calculations is determined, in one embodiment of the invention, by tracing back, through the state transitions, the minimum path metrics for each decoded bit at operation 420. In at least one embodiment of the invention, a reduction in BM and PM calculations can be achieved by taking advantage of certain relationships among the possible state transitions in the received encoded signal.

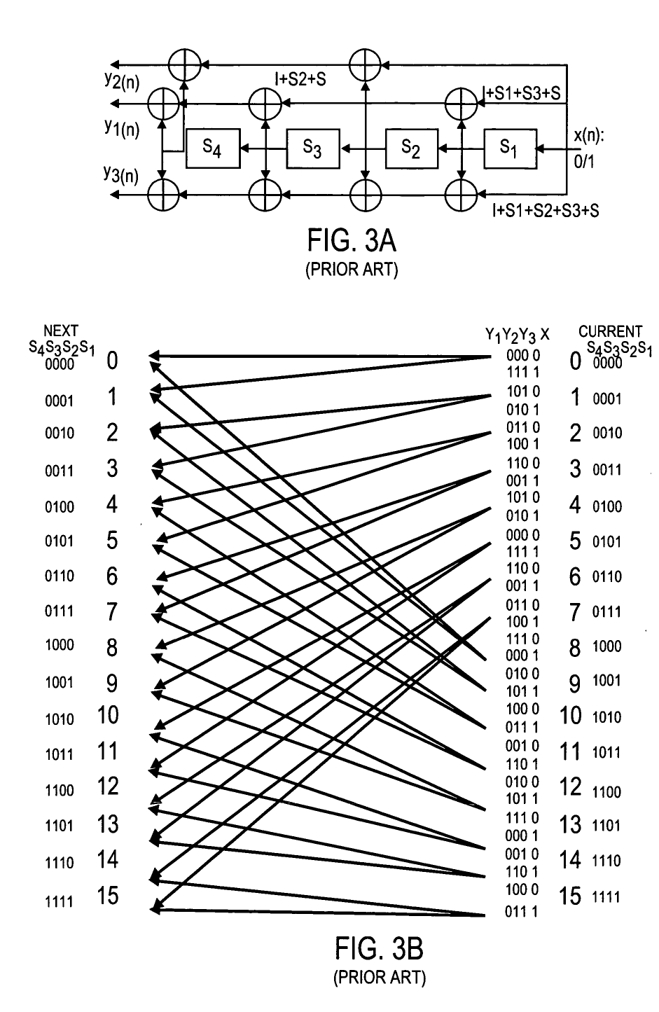

FIG. 5a is a state table that illustrates some of the relationships among possible state transitions according to one embodiment of the invention. First, the table of FIG. 5a illustrates the current state 501 of a Viterbi decoder corresponding to the trellis of FIG. 3b. Next, the table illustrates the encoder input bit 505 to which the current state corresponds. The table also illustrates the encoder output 510 corresponding to the current decoder state as well as the corresponding next state of the decoder 515. The next state corresponds to the path taken through the trellis of FIG. 3b. The trace back bit 520 indicates whether a next state transition is part of an optimal path through the state trellis of FIG. 3b and thus may be part of a survivor path through the trellis to arrive at the final decoder state sequence.

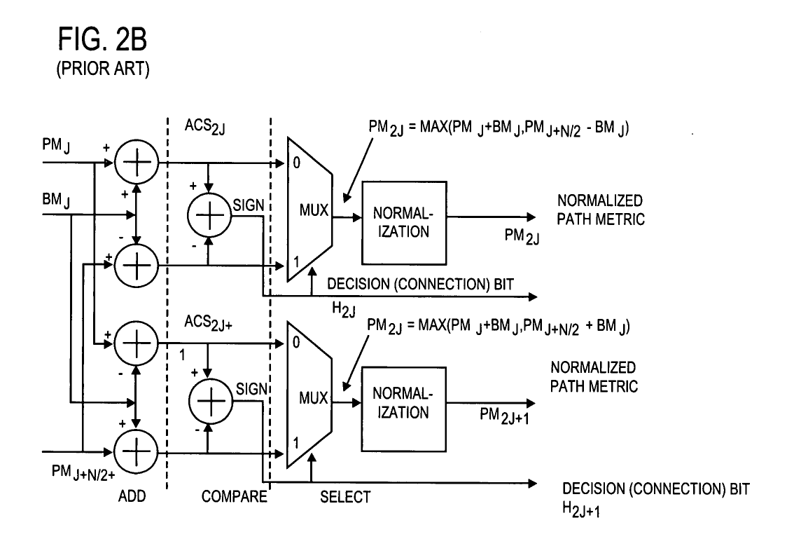

Finally, the table of FIG. 5a illustrates a sequence of branch metrics under the “BM” column 525 that simplifies memory accesses. This is possible, in one embodiment of the invention, because the 16 possible states corresponding to a 16-state ⅓ rate Viterbi encoder, may be modeled using the four BM kernel equations of FIG. 5b by taking advantage of the symmetry of the state transitions with in each ACS butterfly of FIG. 2b.

In FIG. 5b, r0, r1, and r2 represent received values corresponding to the bits of the encoded word. For example, an optimal branch metric sequence for a 16-state ⅓ rate Viterbi decoder, in one embodiment of the invention, can be represented by the state sequence, A, B, C, D, B, A, D, C. Accordingly, at least one embodiment of the invention involves storing the 2ⁿ⁻¹ branch metric values, A,B,C,D, in registers, or, alternatively in memory, and enabling the ACS butterflies to access the branch metric values in the order dictated by the trellis paths of FIG. 3b for a given decoder input sequence.

As ACS iterations are a computationally intensive part of the Viterbi decoding, minimizing the time for each of the 2^{K-2} ACS butterfly calculations is helpful in improving Viterbi decoding performance. In one embodiment of the invention, the performance of ACS butterfly calculations can be improved by taking advantage of architectural features of a particular processor or DSP. For example, in one embodiment of the invention, a DSP calculates the branch metric values and ACS butterfly efficiently by using its registers and accumulators in a dual 16-bit computation mode. Furthermore, the ACS butterfly calculations can be improved by taking advantage of instructions available in a particular DSP instruction set.

For example, in one embodiment of the invention, two new path metrics corresponding to states 2j and 2j+1 of FIG. 5 (nPM[2j]₁ and nPM[2j]₂, nPM[2j+1]₁ and nPM[2j+1]₂ ), are evaluated in parallel using a single vector add-subtract instruction operating on two prior path metrics (oPM[j], oPM[j+N/2]) and stored branch metrics (+BM and −BM) in one embodiment of the invention. The two new path metrics (nPM[2j] and nPM[2j+1]) may then be selected from the results, using a vectored compare-select instruction.

In one embodiment of the invention, a compare-select instruction, such as the VITMAX instruction used in at least one prior art DSP, compares the upper and lower 16-bit values for two given 32-bit registers, and stores the two larger values in a third register. Along with the updated path metrics, VITMAX also may store two decision bits into an accumulator, so that the selected path metric can be tracked. These bits may be used in the trace back operation, to determine the original uuencoded data.

The next branch metric value may be loaded into a processor in parallel with the VITMAX instruction in at least one embodiment of the invention. Furthermore, path metric renormalization stage in FIG. 2b may be avoided altogether, by ensuring proper pre-scaling of input symbols to guarantee maximum path metric range (<2¹⁵), such that individual path metric results can overflow and wrap-around. Therefore, in a 16-state ⅓ rate Viterbi decoder, for example, the input symbols require a resolution up to only 10 signed bits.

In one embodiment of the invention, the entire ACS calculation for a butterfly can be performed in 2 DSP cycles. Furthermore, user-defined instruction parallelism and software pipelining may make the butterfly calculations faster in other embodiments of the invention. For example, a 1-cycle ACS operation can be achieved, in one embodiment of the invention, by implementing the ACS butterfly of FIG. 4b as a dedicated functional unit, such as an execution unit, in a DSP.

The trace back operation traces the minimum length survivor path from the trace back array information, by traversing back from the last state to decipher the decoded bits to the first state. In one embodiment of the invention, the least-significant bit of the current state is the current decoded bit and the state is updated by right shifting the current state and inserting the trace back bit at the most-significant bit position.

The register or memory accesses indicated in the table of FIG. 5a can be handled without extra cycles in one embodiment of the invention, by “straight-line” coding of all the butterflies of the stage. Rather than repeating, or “looping, a software routine for calculating an ACS butterfly N/2 times in order to evaluate all butterflies of each stage, the N/2 loops are represented as separate instances of the software routine in a single loop, for calculating each stage (“straight-line coding”), each instance corresponding to one iteration of the loop. This allows the software routine to avoid memory accesses related to branch metrics, thereby saving DSP cycles.

For example, in one embodiment of the invention, a processor may require only 4 cycles per decoded bit for the 16-state ⅓ rate Viterbi decoder, to compute all the four 16-bit branch metric kernels (A, B, C, D) from the received symbols [r₀ r₁ r₂] and store them in data registers or memory and an additional 16 cycles to perform all the eight ACS butterflies. Prior art requires about 32 cycles for the same situation. Similarly, a ½ rate Viterbi decoder, in another embodiment of the invention, may use only 2 cycles for its 2 branch metrics and 16 cycles for the ACS operation while the prior art needs a total of 24 cycles. For other encoding rates, such as ¼ and ⅙, exploiting the repeated nature of the encoder polynomials can reduce the cycles required to compute the branch metrics. Accordingly, this technique can be generalized to other constraint lengths and rates.

Embodiments of the invention described herein may be implemented with circuits using complementary metal-oxide-semiconductor devices, or “hardware”, or using a set of instructions stored in a medium that when executed by a machine, such as a processor, perform operations associated with embodiments of the invention, or “software”. Alternatively, embodiments of the invention may be implemented using a combination of hardware and software.

While the invention has been described with reference to illustrative embodiments, this description is not intended to be construed in a limiting sense. Various modifications of the illustrative embodiments, as well as other embodiments, which are apparent to persons skilled in the art to which the invention pertains are deemed to lie within the spirit and scope of the invention.

1. An apparatus comprising:
means for storing 2ⁿ⁻¹ branch metric values to be used in a 1/n rate signal decoder to a storage device;
means for loading from the storage device no more than the 2ⁿ⁻¹ branch metric values to generate 2^{K-1} signal states for each of an n-bit signal value received by a communications signal decoder.

2. The apparatus of claim 1 further comprising means for performing 2^{K-2} add, compare, select (ACS) butterfly calculations corresponding to the no more than 2ⁿ⁻¹ branch metric values.

3. The apparatus of claim 2 wherein the means for performing 2^{K-2} ACS butterfly calculations comprises digital signal processor (DSP) registers and accumulators being used in 16-bit computation mode.

4. The apparatus of claim 3 comprising means for evaluating two path metrics in parallel.

5. The apparatus of claim 4 wherein the means for evaluating two path metrics in parallel comprises a single vector add-subtract instruction to operate on two prior path metrics and stored branch metrics.

6. The apparatus of claim 4 wherein the means for evaluating two path metrics in parallel comprises a VITMAX instruction to compare the upper and lower 16-bit values of two 32-bit DSP registers and store the larger of the two in a third register.

7. The apparatus of claim 6 wherein the VITMAX instruction is to store two decision bits into an accumulator in order to allow a selected path metric to be tracked.

8. The apparatus of claim 7 wherein the 2^{K-2} ACS butterfly calculations are to be performed within two DSP processing cycles.

9. A method to perform a Viterbi decoding algorithm comprising:
initializing path metric buffers and trace back buffers;
evaluating branch metric (BM) kernel equations;
storing the result of the BM evaluations;
performing path metric evaluations corresponding to each BM evaluation.

10. The method of claim 9 wherein the Viterbi decoding algorithm is to be performed by a 16-state, ⅓ rate decoder.

11. The method of claim 9 further comprising performing add, compare, and select (ACS) calculations to determine a most probable next state transition for each current state of an input signal to the Viterbi decoding algorithm.

12. The method of claim 11 further comprising determining a maximum path metric values corresponding to the path metric evaluations and storing them.

13. The method of claim 12 further comprising tracing back through state transitions to determine the minimum path between each bit state decoded by the Viterbi decoding algorithm.

14. The method of claim 9 wherein the number of BM equations is no more than 4.

15. The method of claim 11 wherein the ACS calculations comprise the BM calculations and path metric calculations for each current state.

16. The method of claim 11 wherein the ACS calculations comprise path metric calculations and not BM calculations for each current state.

17. The method of claim 15 wherein the number of BM and path metric calculations are reduced by taking advantage of symmetry among a table of possible next state transitions corresponding to a received encoded signal.

18. A processor comprising:
a storage unit to store 2ⁿ⁻¹ branch metric values to be used in a 1/n rate signal decoder to a storage device;
a loading unit to load from the storage device no more than the 2ⁿ⁻¹ branch metric values to generate 2^{K-1} signal states for each of an n-bit signal value received by a communications signal decoder.

19. The processor claim 18 wherein the storage unit is at least one memory location and the loading unit is a memory interface unit.

20. The processor of claim 19 further comprising add, compare, and select (ACS) logic to perform 2^{K-2} ACS butterfly calculations corresponding to the no more than 2ⁿ⁻¹ branch metric values.

21. The processor of claim 20 wherein the ACS logic comprises digital signal processor (DSP) registers and accumulators to be used in 16-bit computation mode.

22. The processor of claim 21 comprising path metric logic to evaluating two path metrics in parallel.

23. The processor of claim 22 wherein the path metric logic is to perform a VITMAX instruction to compare the upper and lower 16-bit values of two 32-bit DSP registers and store the larger of the two in a third register.

24. The processor of claim 23 wherein the VITMAX instruction is to store two decision bits into an accumulator in order to allow a selected path metric to be tracked.

25. The processor of claim 24 wherein the 2^{K-2} ACS butterfly calculations are to be performed within two DSP processing cycles.

26. A machine-readable medium having stored thereon a set of instructions, which if executed by a machine, cause the machine to perform a method comprising:
initializing path metric buffers and trace back buffers;
evaluating no more than 4 branch metric (BM) kernel equations;
storing the result of the BM evaluations;
evaluating path metric calculations corresponding to each BM evaluation.

27. The machine-readable medium of claim 26 further comprising instructions to determine the maximum path metric values corresponding to the path metric evaluation and store them.

28. The machine-readable medium of claim 27 further comprising instructions to trace back through state transitions to determine a minimum path between each bit state decoded by the Viterbi decoding algorithm.

29. The machine-readable medium of claim 28 further comprising instructions to reduce the number of BM and path metric calculations by taking advantage of symmetry among a table of possible next state transitions corresponding to a received encoded signal.
